(19) United States
(12) Patent Application Publication
(10) Pub. No.: US 2013/0154049 A1
(43) Pub. Date: Jun. 20, 2013

(54) Integrated Circuits on Ceramic Wafers Using Layer Transfer Technology

(71) Applicants: George Imthurn, San Diego, CA (US); Tyler Branden Benner, Chula Vista, CA (US); Anthony Mark Miscione, Ramona, CA (US)

(72) Inventors: George Imthurn, San Diego, CA (US); Tyler Branden Benner, Chula Vista, CA (US); Anthony Mark Miscione, Ramona, CA (US)

(21) Appl. No.: 13/528,825

(22) Filed: Jun. 20, 2012

Related U.S. Application Data
(60) Provisional application No. 61/500,069, filed on Jun. 22, 2011.

(51) Int. Cl. H01L 27/12; H01L 21/762

(52) U.S. Cl. CPC H01L 27/1203; H01L 21/76251
USPC 257/506; 438/458

(57) ABSTRACT

Novel integrated circuits (ICs) on ceramic wafers and methods of fabricating ICs on ceramic wafers are disclosed. In one embodiment, an active layer comprising IC circuit components is coupled to a selected wafer comprising a ceramic. A surface of the ceramic is processed to enable direct bonding between the selected wafer and the active layer. Another embodiment comprises an active layer comprising IC circuit components and a selected wafer comprising a ceramic and an intermediate layer. A surface of the intermediate layer is processed to enable direct bonding. In some embodiments the intermediate layer comprises a material selected from the following: silicon carbide, silicon dioxide, silicon nitride and diamond. Methods of fabrication are described, wherein layer transfer technology is employed to form active layers and to couple the active layers to the selected wafers.

### CROSS-REFERENCE TO RELATED APPLICATION—CLAIM OF PRIORITY

This patent application claims the benefit of priority under 35 U.S.C. §119 (e) to commonly-assigned U.S. Provisional Patent Application 61/500,069, filed Jun. 22, 2011, entitled “Integrated Circuits on Ceramic Wafers Using Layer Transfer Technology” (ATTY. DOCKET NO. PER-047-PROV). The above-cited provisional patent application is hereby incorporated by reference herein in its entirety as if set forth in full.

### BACKGROUND

1. Field

The present disclosure relates to electronic integrated circuits (ICs), and more specifically to ICs formed on ceramic wafers using layer transfer technology.

2. Description of Related Art

For reasons well known to persons skilled in the arts of IC design, many types of ICs may be advantageously implemented using silicon-on-insulator (SOI) technology. For example, radio frequency (RF) ICs benefit from having in insulating substrate because dissipation of RF signals in the substrate, and coupling of RF signals between devices, are reduced. For some applications, SOI RF ICs may be fabricated on commercially available SOI wafers comprising a silicon substrate, a buffer layer (typically a buried-oxide (BOX) silicon dioxide layer) bonded to the substrate, and a thin silicon layer bonded to the buffer layer. Devices such as transistors may be fabricated in the thin silicon layer, and the buffer layer provides electrical isolation between IC components. However, because the buffer layer is relatively thin (with a typical thickness less than a micrometer), capacitive coupling of RF signals between devices fabricated in the thin silicon layer and the conductive silicon substrate may cause poor performance for many types RF ICs. For this reason, replacing the silicon substrate with a fully insulating substrate is advantageous.

One type of fully insulating substrate material suitable for IC fabrication is sapphire. Sapphire wafers are commercially available, and various methods for fabricating ICs on sapphire wafers are well known. However, sapphire wafers are expensive due to the cost of the sapphire material and the processing cost of manufacturing the wafers. Another disadvantage of sapphire wafers is the relatively low thermal conductivity of sapphire, which is 35 W/m-K. Thermal conductivity is important because it facilitates dissipation of heat from IC devices such as transistors. Although the thermal conductivity of sapphire is adequate for many SOI IC designs, improved performance, especially for high-power devices, could be achieved by using a material having a higher thermal conductivity than sapphire.

To overcome the limitations of prior art, the present teachings disclose novel insulating wafers, ICs coupled with the insulating wafers, and methods for fabricating the insulating wafers and the ICs coupled with the insulating wafers.

### SUMMARY

The present teachings disclose novel integrated circuits (ICs) on ceramic wafers, and methods of fabrication. One embodiment of the inventive concept comprises an active layer comprising IC circuit components, and a selected wafer comprising a ceramic. The active layer is coupled to a surface of the ceramic by means of direct bonding methods. The surface of the ceramic is processed to enable direct bonding of the active layer to the surface of the ceramic. In one embodiment, the ceramic comprises silicon carbide (SiC). In another embodiment, the ceramic comprises aluminum nitride (AlN).

Another embodiment comprises an active layer comprising IC circuit components, and a selected wafer comprising a ceramic and an intermediate layer. The active layer is coupled to a first surface of the intermediate layer, and a second surface of the intermediate layer is coupled to the first surface of the ceramic. The first surface of the intermediate layer is processed to enable direct bonding of the active layer to the first surface of the intermediate layer. In some embodiments the intermediate layer comprises at least one material selected from the following materials: silicon carbide, silicon dioxide, silicon nitride and diamond.

Another embodiment comprises a method for fabricating ICs. At a FIRST STEP of the method, a selected wafer comprising a ceramic is processed to have a first surface with a surface roughness in the range of less than 5 nm At a SECOND STEP, an active layer is formed on a silicon substrate, wherein the active layer comprises IC circuit components. At a THIRD STEP, a planarization layer is formed on a first surface of the active layer. At a FOURTH STEP, a transfer wafer is coupled to the planarization layer. At a FIFTH STEP, the silicon substrate is removed from the active layer by etching and/or grinding processes, thereby exposing a second surface of the active layer. At a SIXTH STEP, the second surface of the active layer is coupled to the first surface of the ceramic wafer. At a SEVENTH STEP, the transfer wafer and the planarization layer are removed from the active layer, thereby exposing the first surface of the active layer. Optionally, further processing steps may be performed to provide a finished product.

Another embodiment comprises a second method for fabricating ICs. At a FIRST STEP of the second method, a selected wafer is formed, comprising a ceramic wafer and an intermediate layer, wherein a first surface of the intermediate layer is coupled to a first surface of the ceramic wafer. At a SECOND STEP, a second surface of the intermediate layer is processed to have a surface roughness in the range of less than 5 nm. At a THIRD STEP, an active layer is formed on a silicon substrate, wherein the active layer comprises IC circuit components. At a FOURTH STEP, a planarization layer is formed on a first surface of the active layer. At a FIFTH STEP, a transfer wafer is coupled to the planarization layer. At a SIXTH STEP, the silicon substrate is removed from the active layer by etching and/or grinding processes, thereby exposing a second surface of the active layer. At a SEVENTH STEP, the second surface of the active layer is coupled to the second surface of the intermediate layer. At an EIGHTH STEP, the transfer wafer and the planarization layer are removed from the active layer, thereby exposing the first surface of the active layer. Optionally, further processing steps may be performed to provide a finished product. In some embodiments the intermediate layer comprises a material selected from the following materials: silicon carbide, silicon dioxide, silicon nitride and diamond. In some embodiments, the intermediate layer is formed on the first surface of the ceramic wafer via a deposition process such as chemical vapor deposition (CVD).

### BRIEF DESCRIPTION OF THE DRAWINGS

FIG. 1 schematically illustrates a cross-section of an active layer coupled to a selected wafer, wherein the selected wafer comprises a ceramic.

FIG. 2 schematically illustrates a cross-section of an active layer coupled to a selected wafer, wherein the selected wafer comprises a ceramic wafer and an intermediate layer.

FIG. 3 is a flow-chart for a method for forming ICs.

FIG. 4 schematically illustrates a cross-section of an active layer formed on a silicon substrate, in accordance with the method illustrated by FIG. 3.

FIG. 5 schematically illustrates a cross-section of an in-process configuration of layers, in accordance with the method illustrated by FIG. 3.

FIG. 6 schematically illustrates a cross-section of another in-process configuration of layers, in accordance with the method illustrated by FIG. 3.

FIG. 7 is a flow-chart for another method for forming ICs.

FIG. 8 schematically illustrates a cross-section of a selected wafer, wherein the selected wafer comprises a ceramic wafer and an intermediate layer.

FIG. 9 schematically illustrates a cross-section of an active layer formed on a silicon substrate, in accordance with the method illustrated by FIG. 7.

FIG. 10 schematically illustrates a cross-section of another in-process configuration of layers, in accordance with the method illustrated by FIG. 7.

FIG. 11 schematically illustrates a cross-section of another in-process configuration of layers, in accordance with the method illustrated by FIG. 7.

Like reference numbers and designations in the various drawings indicate like elements.

### DETAILED DESCRIPTION

Throughout this description, embodiments and variations are described for the purpose of illustrating uses and implementations of the inventive concept. The illustrative description should be understood as presenting examples of the inventive concept, rather than as limiting the scope of the concept as disclosed herein.

The present teachings disclose novel integrated circuits (ICs) on ceramic wafers, and methods of fabrication. For prior art silicon-on-insulator (SOI) ICs, sapphire has been used as a wafer material because of its excellent electrical and mechanical properties. However, sapphire wafers are expensive, and the thermal conductivity of sapphire (35 W/m-K) is relatively low compared to Si. Ceramic materials have good electrical properties, are less expensive than sapphire, and many ceramic materials have significantly better thermal conductivity than sapphire. As examples, aluminum nitride ceramic has a thermal conductivity of 170 W/m·K, and silicon carbide ceramic has a thermal conductivity of 115 W/m·K.

However, according to prior art teachings, there are limitations that impede the use of ceramics for the fabrication of ICs. Ceramics are commonly fabricated by sintering techniques, wherein a binding material (such as boron) is mixed with a polycrystalline powder and sintered or hot-pressed to form a solid shape. For the teachings herein, a SiC wafer formed by chemical vapor deposition (CVD) shall be defined as a “ceramic wafer,” and such a CVD SiC wafer shall be designated as comprising a “ceramic” or “ceramic material.” According to prior art, the resulting ceramic material cannot be employed for IC wafers for two reasons: First, IC fabrication methods commonly employ elevated temperatures at which the binding material or other impurities from the ceramic can diffuse from the wafer and contaminate the silicon of the ICs, thereby altering the electrical properties of the silicon. Second, because the ceramic materials generally are difficult to lap and/or polish to a sufficiently low level of roughness as required for IC fabrication. The teachings disclosed herein overcome these limitations of prior art.

By using layer transfer technology, wherein the silicon IC devices are first fabricated on a silicon wafer and then transferred to a selected wafer comprising a ceramic, the problem of contamination from ceramic materials is overcome because the ceramic is not subjected to the elevated temperatures of IC fabrication. To use layer transfer technology, the root-mean-square (rms) surface roughness of the ceramic wafer generally must be in a range of less than 5 nm. This can be accomplished either by processing a surface of ceramic using suitable methods, or by forming an intermediate layer on the ceramic surface, and processing a surface of the intermediate layer using suitable methods. Suitable methods may include, without limitation, grinding, etching, Chemical Mechanical Polishing (CMP) and metal-disk polishing. CMP, which may use diamond slurry and/or other techniques, is a method well known to persons skilled in the arts of polishing materials such as ceramics and diamond. Metal-disk polishing utilizes a metal disk, such as Cu, that is impregnated with an abrasive material such as diamond powder. Metal-disk polishing is also a method well known to persons skilled in the arts of polishing materials such as ceramics and diamond.

ICs on Ceramic Wafers

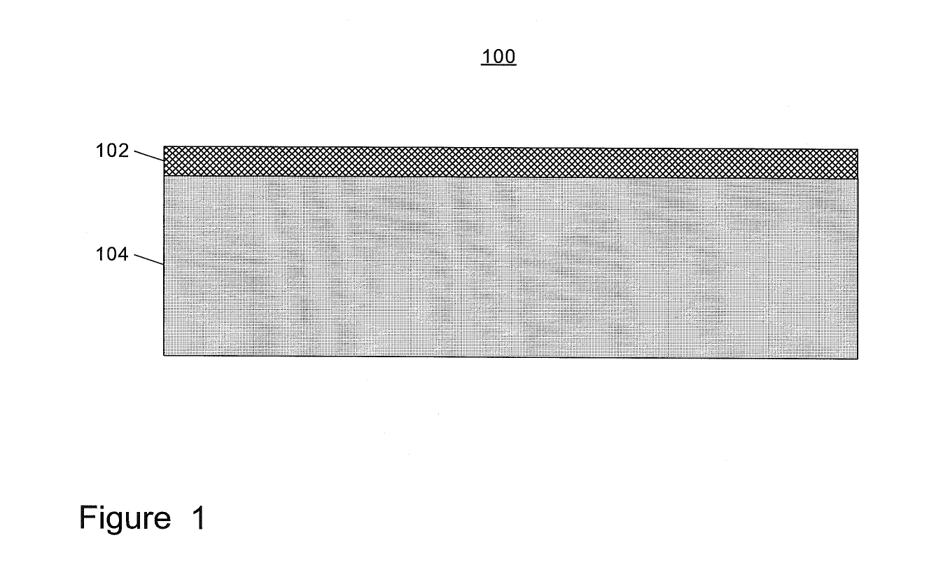

FIG. 1 is a diagram illustrating a cross-section of an IC wafer 100, comprising an active layer 102 coupled to a selected wafer 104. The active layer 102 comprises one or more ICs (not shown in the FIG. 1), and may include, without limitation, IC components (not shown the FIG. 1) such as transistors, resistors, capacitors, diodes, interconnects, insulating layers, a buffer layer, etc. A buffer layer (not shown in the FIGURES) may include, without limitation, a buried-oxide (BOX) layer. The buffer layer may be used as an etch-stop and/or to protect the active layer during processing STEPS such as removing a Si substrate, as described hereinbelow.

The selected wafer 104 is a wafer comprising, without limitation, a material selected from the following materials: hot-pressed SiC, sintered SiC, CVD SiC, and aluminum nitride.

The active layer 102 is coupled to the selected wafer 104 by direct bonding. “Direct bonding” is a bonding method well known to persons skilled in the arts of IC layer transfer technology and wafer bonding, wherein two clean, flat surfaces are bonded together by bringing them into proximity so that bonds may form across the interface between the two surfaces. Various surface treatments prior to joining, and annealing processes subsequent to joining, may be employed to provide strong bonding between the materials, as are well known to persons skilled in the arts of wafer bonding. For example, a nitrogen plasma may be employed to facilitate direct bonding between wafers. In general, for direct bonding to be successful, the rms roughness of the surfaces to be joined should be less than 5 nm.

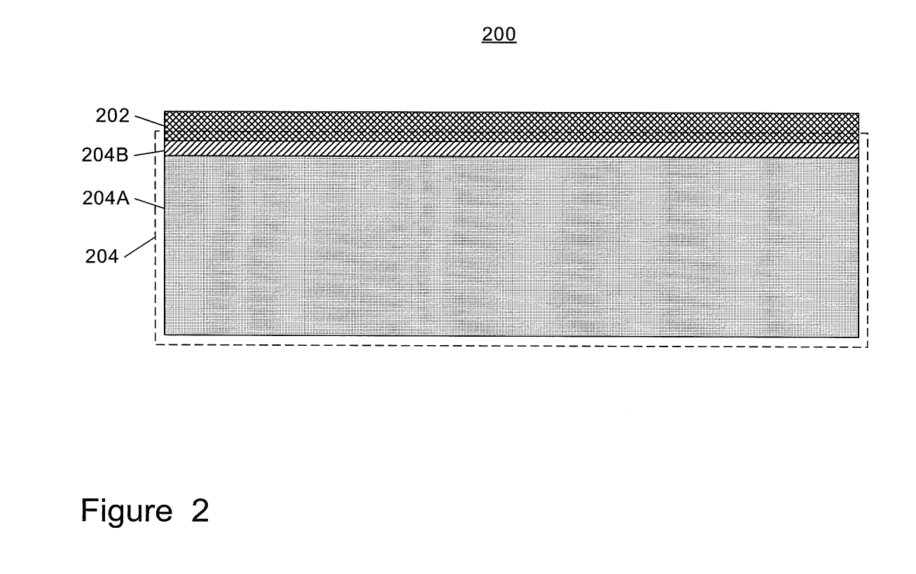

FIG. 2 is a diagram illustrating a cross-section of an IC wafer 200, comprising an active layer 202 coupled to a selected wafer 204. The active layer 102 comprises one or more ICs (not shown in the FIG. 2), and may include, without limitation, IC components (not shown the FIG. 2) such as transistors, resistors, capacitors, diodes, interconnects, insulating layers, a buffer layer (e.g., a BOX layer), etc.

The selected wafer 204 comprises a ceramic wafer 204A and an intermediate layer 204B. The ceramic wafer 204A comprises a ceramic material. The ceramic material may comprise, without limitation, at least one of the following materials: hot-pressed SiC, sintered SiC, CVD SiC, and aluminum nitride.

The intermediate layer 204B is formed on the ceramic wafer 204B. The intermediate layer 204B comprises a material that may be selected, without limitation, from the following materials: silicon carbide, silicon dioxide, silicon nitride and diamond. In some embodiments, the intermediate layer is formed on the first surface of the ceramic via a deposition process such as chemical vapor deposition (CVD). For ICs having high-power devices such as power transistors, diamond is an advantageous material because of its high thermal conductivity relative to ceramic materials. For this reason, a diamond layer provides the advantage of increased lateral thermal diffusion, and increasing the thickness of the diamond layer provides improved thermal performance. For ICs in which heat dissipation is less critical, intermediate layer materials with a thermal conductivity less than a ceramic material may selected, and may be desirable due to lower cost of fabrication and processing. For intermediate layer materials with a thermal conductivity less than a ceramic material, the thermal impedance of the intermediate layer 204B may be reduced by reducing its thickness.

The active layer 202 is coupled to a surface of the intermediate layer 204B by direct bonding, as described hereinabove in reference to the FIG. 1.

Methods for Fabricating ICs on Ceramic Wafers

It will be understood by persons skilled in the IC design and fabrication arts that hundreds of intermediate steps may be required to form ICs. Conventional IC processing steps such as photolithography, masking, etching, mask stripping, ion implantation, and deposition of metal layers, dielectric layers, etc., are well known to persons skilled in the arts of IC manufacturing, and they will understand where such steps may be required. Further, methods for fabricating ICs using layer transfer technology are also well known to persons skilled in the IC design and fabrication arts. Therefore, only steps relevant to the inventive methods and apparatus are described in detail herein.

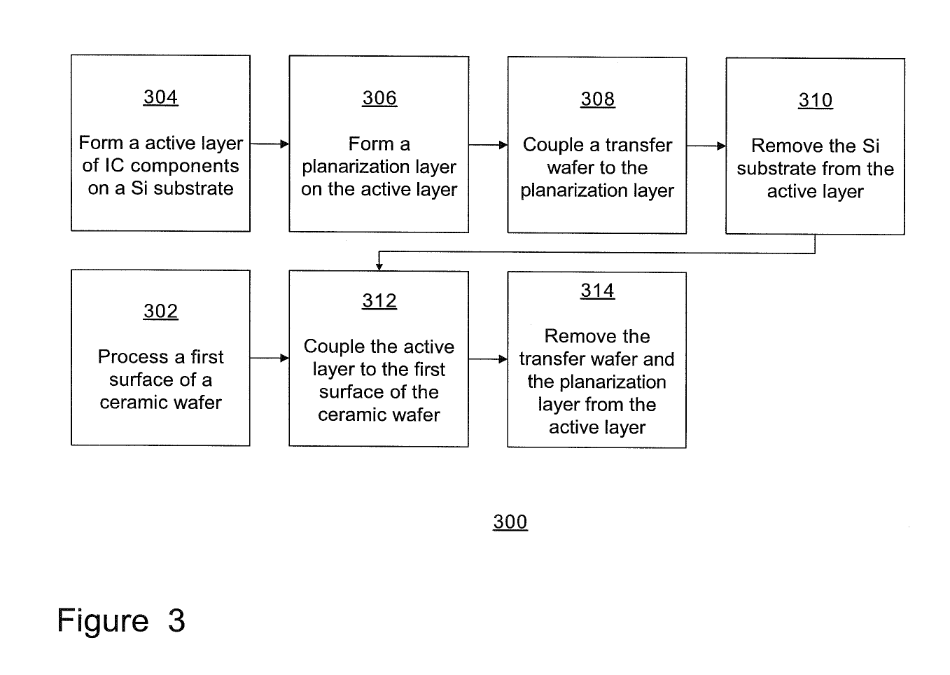

FIG. 3 is a flow-chart of a method 300 for fabricating ICs on ceramic wafers. The method 300 begins at a STEP 302, wherein a surface of a selected wafer, like the selected wafer 104 described in reference to the FIG. 1, is processed by a polishing method. The polishing method may include, without limitation, grinding, etching, CMP and metal-disk polishing. The surface of the selected wafer is processed to have an rms surface roughness in the range of less than 5 nm. The STEP 302 flows to a STEP 312, after STEPS 304 to 310 are performed, as described hereinbelow.

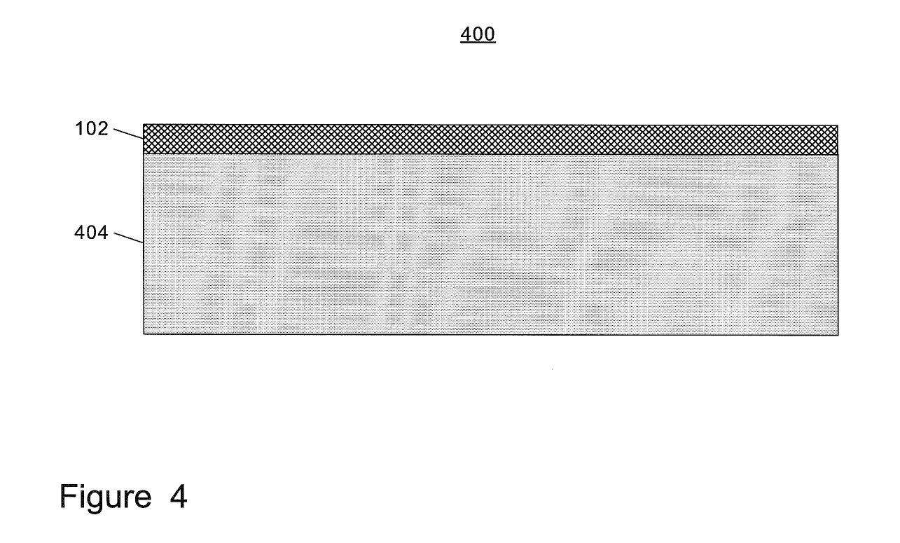

At a STEP 304, an active layer 102 is formed on a silicon substrate 404 (refer to the FIG. 4). Prior to processing the silicon substrate 404 to form the active layer 102, the silicon substrate 404 may comprise, without limitation, a silicon wafer, or a silicon-on-insulator (SOI) wafer. SOI wafers are commercially available, and methods for fabricating active layers on silicon wafers and SOI wafers are well known to persons skilled in the arts of IC manufacture. The active layer 102 may include, without limitation, IC components (not shown) such as transistors, resistors, capacitors, diodes, interconnects, insulating layers, a buffer layer (e.g., a BOX layer), etc.

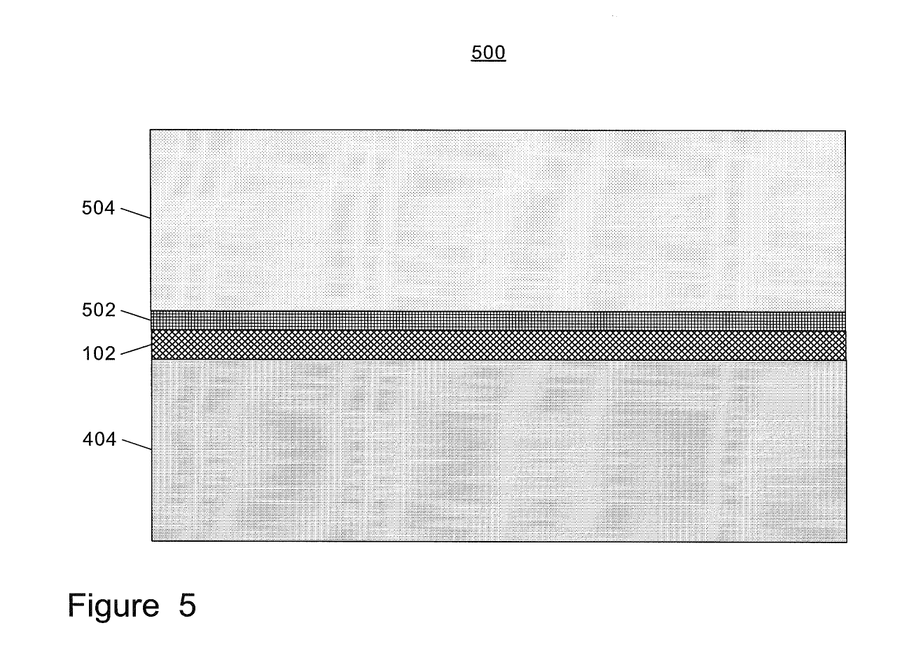

At a STEP 306, planarization layer 502 (shown in FIG. 5) is formed on the active layer 102. In one example, the planarization layer 502 may comprise polymer material applied by a spin-on method or other known method of manufacture. In another example, the planarization layer 502 may comprise a silicon oxide layer that is deposited and processed to provide a surface suitable for direct bonding, adhesive bonding, or other bonding methods known to persons skilled in the arts of layer transfer technology.

Proceeding to a next STEP 308, a transfer wafer 504 (shown in the FIG. 5), is coupled to the planarization layer 502. The transfer wafer 504 may comprise, without limitation: a silicon wafer, a sapphire wafer, a quartz wafer, or a glass wafer. The transfer wafer 504 may be coupled or bonded to the planarization layer 502 by means of an adhesive (e.g., a UV-laser release adhesive, a thermal release adhesive, a solvent-release adhesive), or by means of direct bonding, or other bonding methods. In some embodiments (not shown), the transfer wafer 504 may be coupled directly to the active layer 102, without implementing the planarization layer 502.

At a STEP 310, the bulk of the silicon substrate 404 (as shown in the FIG. 5) is removed from the active layer 102. The silicon substrate 404 may be removed by grinding and/or etching processes, or other methods. Processes and methods for removing substrates from active layers are well known to persons skilled in the arts of layer transfer technology.

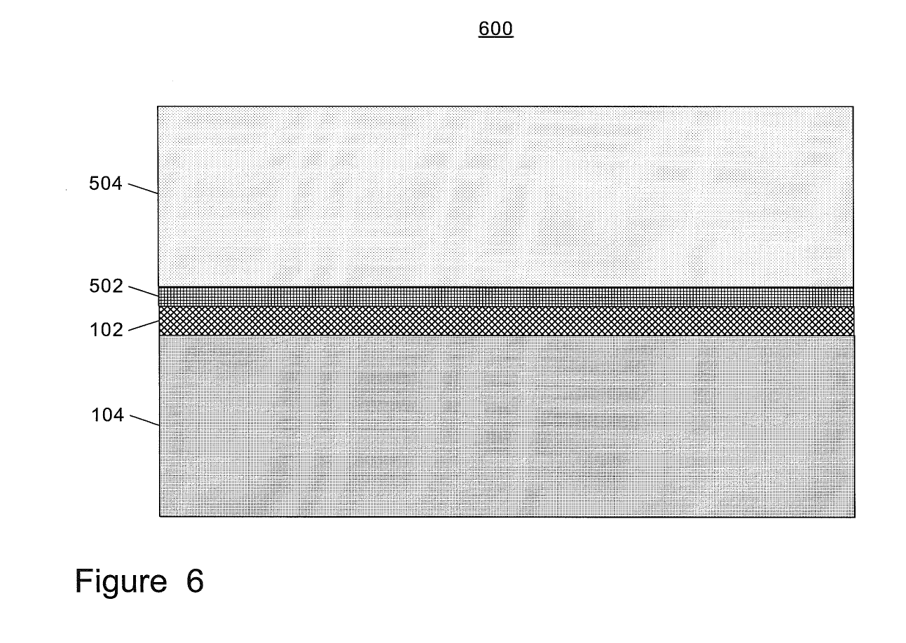

At a STEP 312, the active layer 102 is coupled to the selected wafer 104 (processed according to the STEP 302, described above) as shown in FIG. 6. In some embodiments, the coupling may be effected by means of direct bonding, or other bonding methods.

The method 300 concludes at a STEP 314, wherein the transfer wafer 504 and the planarization layer 502 are removed. Techniques for removing transfer wafers and planarization layers are well known to persons skilled in the arts of layer transfer technology. Optionally, further processing STEPS (not shown), may be implemented to provide a finished product.

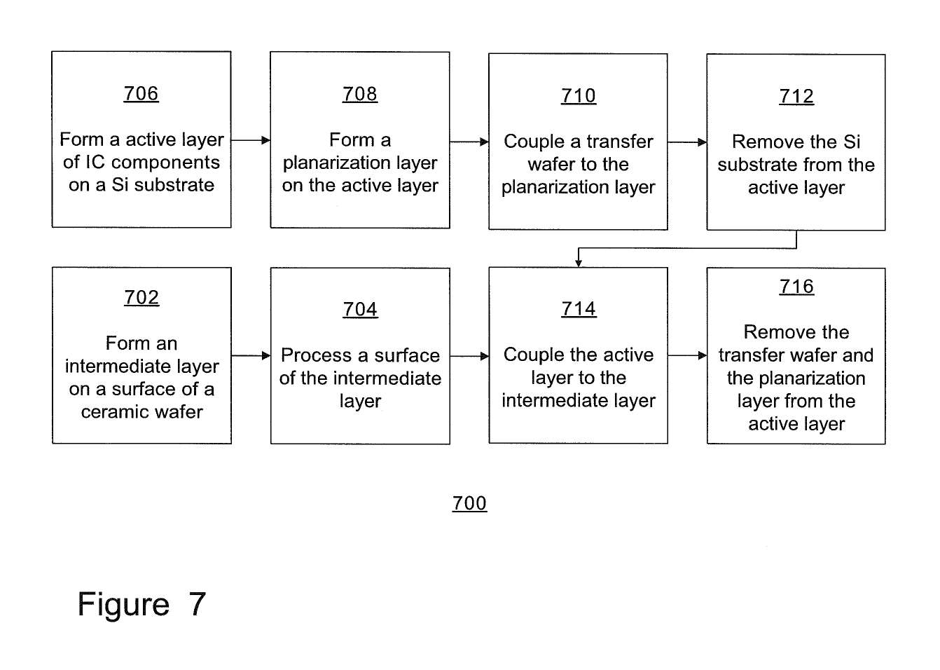

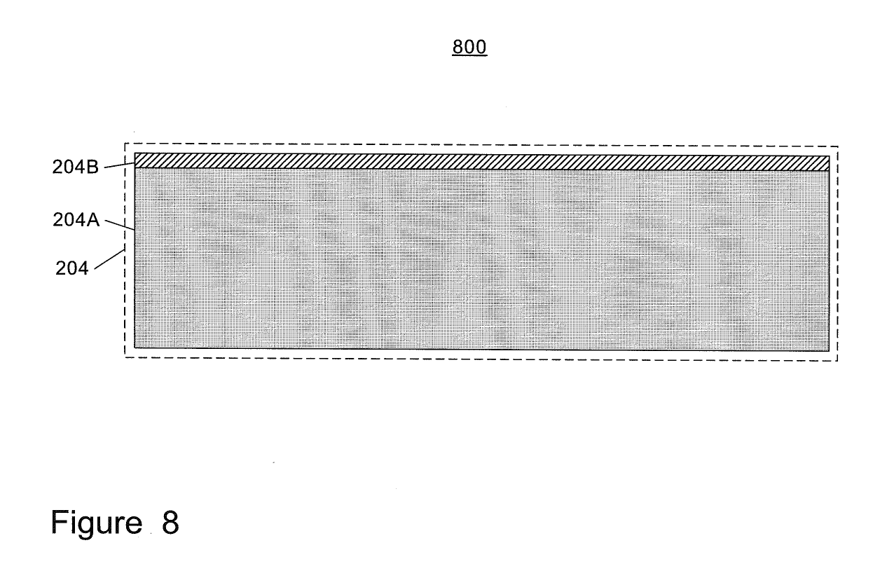

FIG. 7 is a flow-chart of a method 700 for fabricating ICs on ceramic wafers. The method 700 begins at a STEP 702, wherein an intermediate layer 204B is formed on a ceramic wafer 204A, as shown in FIG. 8. The intermediate layer 204B may comprise, without limitation, a material selected from the following materials: silicon carbide, silicon dioxide, silicon nitride and diamond. In some embodiments, the intermediate layer is formed on the first surface of the ceramic via a deposition process such as CVD. A selected wafer 204 comprises the ceramic wafer 204A and the intermediate layer 204B.

At a STEP 704, a surface of the intermediate layer 204B is processed by a polishing method. The polishing method may include, without limitation, grinding, etching, CMP and metal-disk polishing. The surface of the intermediate layer 204B is processed to have an rms surface roughness in the range of less than 5 nm. The method 700 flows from the STEP 704 to a STEP 714, as shown. STEPS 706 to 712 (described below), are also performed prior to executing the STEP 714.

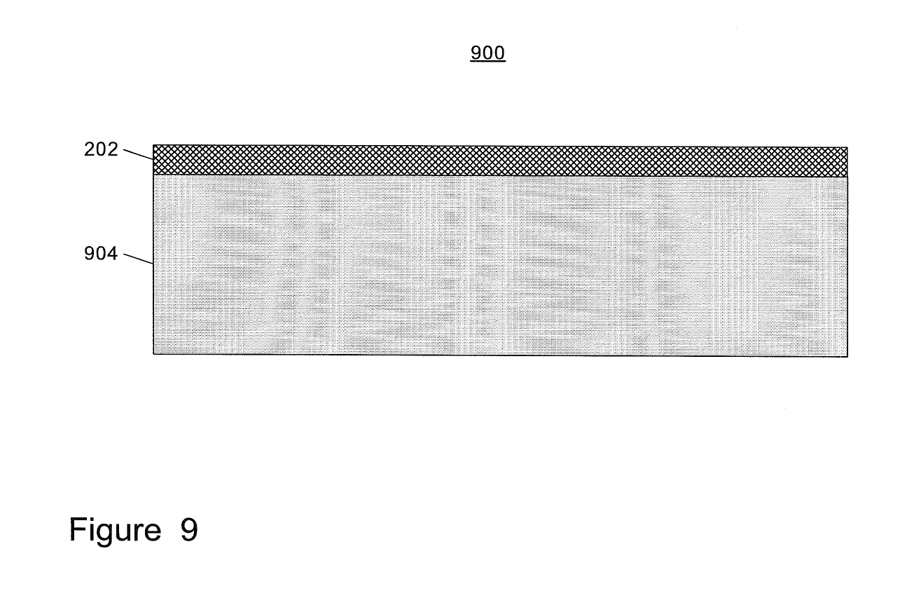

At a STEP 706, an active layer 202 is formed on a silicon substrate 904, as shown in FIG. 9. Prior to processing the silicon substrate 404 to form the active layer 102, the silicon substrate 904 may comprise, without limitation, a silicon wafer, or a silicon-on-insulator (SOI) wafer. The active layer 202 may include, without limitation, IC components (not shown) such as transistors, resistors, capacitors, diodes, interconnects, insulating layers, a buffer layer (e.g., a BOX layer), etc.

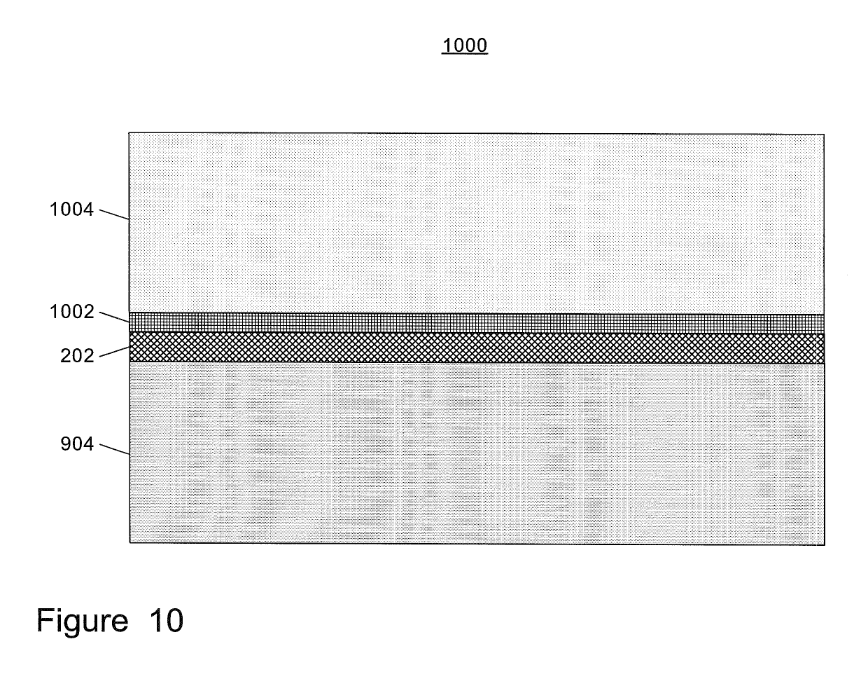

At a STEP 708, planarization layer 1002 (shown in FIG. 10) is formed on the active layer 202. In one example, the planarization layer 1002 may comprise polymer material applied by a spin-on method or other known method of manufacture. In another example, the planarization layer 1002 may comprise an oxide layer that is deposited and polished to provide a surface suitable for direct bonding or adhesive bonding.

Proceeding to a next STEP 710, a transfer wafer 1004 (shown in FIG. 10), is coupled to the planarization layer 1002. The transfer wafer 1004 may comprise, without limitation: a silicon wafer, a sapphire wafer, a quartz wafer, or a glass wafer. The transfer wafer 1004 may be coupled or bonded to the planarization layer 1002 by means of an adhesive, direct bonding or other methods known to persons skilled in the arts of layer transfer technology. In some embodiments (not shown), the transfer wafer 1004 may be coupled directly to the active layer 202.

At a STEP 712, the silicon substrate 904 (see FIG. 10) is removed from the active layer 202. The silicon substrate 904 may be removed by grinding and/or etching processes, or other methods well known to persons skilled in the arts of layer transfer technology.

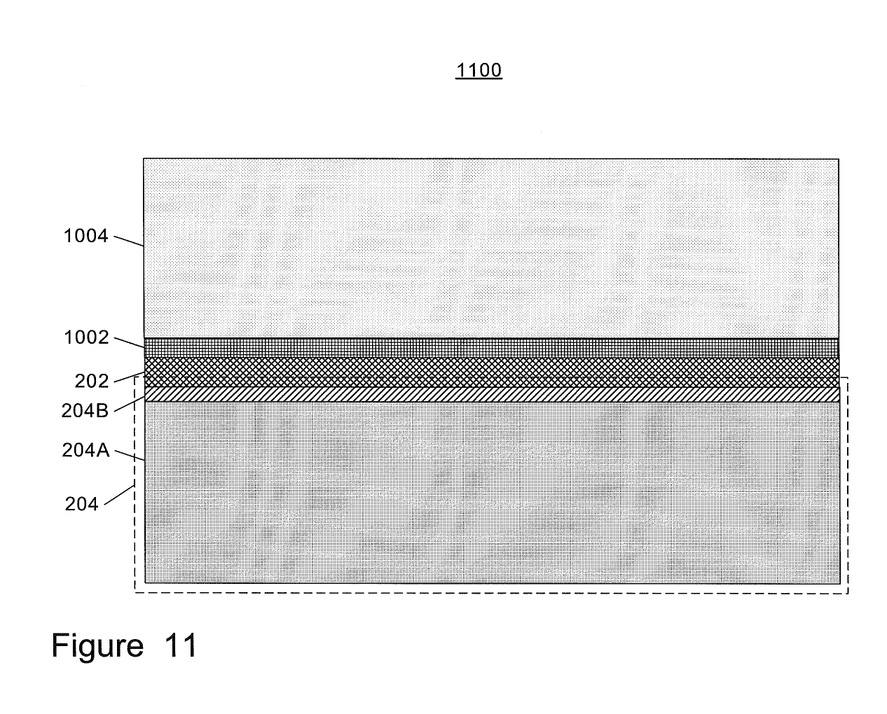

At a STEP 714, the active layer 202 is coupled to the intermediate layer 204B (in reference to the STEP 704), as shown in FIG. 11. In some embodiments, the coupling may be effected by means of direct bonding.

The method 700 concludes at a STEP 716, wherein the transfer wafer 1004 and the planarization layer 1002 are removed. Optionally, further processing STEPS (not shown), may be implemented to provide a finished product.

A number of embodiments of the present inventive concept have been described. Nevertheless, it will be understood that various modifications may be made without departing from the scope of the inventive teachings. Accordingly, it is to be understood that the inventive concept is not to be limited by the specific illustrated embodiments, but only by the scope of the appended claims. The description may provide examples of similar features as are recited in the claims, but it should not be assumed that such similar features are identical to those in the claims unless such identity is essential to comprehend the scope of the claim. In some instances the intended distinction between claim features and description features is underscored by using slightly different terminology.

What is claimed is:

1. An integrated circuit (IC) coupled to a wafer, comprising:
a) a wafer comprising a ceramic material; and,
b) an active layer comprising the IC, wherein the active layer comprising the IC is coupled to the wafer comprising the ceramic material by direct bonding.

2. The integrated circuit (IC) coupled to a wafer of claim 1, wherein the ceramic material is selected from the following materials: hot-pressed silicon carbide (SiC), sintered SiC, SiC formed by chemical vapor deposition (CVD SiC), and aluminum nitride (AlN).

3. An integrated circuit (IC) coupled to a wafer, comprising:
a) a wafer comprising a ceramic material;
b) an intermediate layer formed on a surface of the wafer comprising the ceramic material; and,
c) an active layer comprising the IC, wherein the active layer comprising the IC is coupled to the intermediate layer by direct bonding.

4. The integrated circuit (IC) coupled to a wafer of claim 3, wherein the ceramic material is selected from the following materials: hot-pressed silicon carbide (SiC), sintered SiC, SiC formed by chemical vapor deposition (CVD SiC), and aluminum nitride (AlN).

5. The integrated circuit (IC) coupled to a wafer of claim 3, wherein the intermediate layer comprises a material selected from the following materials: silicon carbide, silicon dioxide, silicon nitride, and diamond.

6. The integrated circuit (IC) coupled to a wafer of claim 5, wherein the intermediate layer is formed by chemical vapor deposition.

7. A method for forming an integrated circuit (IC) coupled to a wafer, comprising:
a) polishing a surface of a ceramic wafer;
b) forming an active layer comprising the IC on a silicon substrate;
c) forming a planarization layer on the active layer comprising the IC;
d) coupling a transfer wafer to the planarization layer;
e) removing the silicon substrate from the active layer comprising the IC; and,
f) coupling the active layer comprising the IC to the surface of the ceramic wafer.

8. The method for forming an integrated circuit (IC) coupled to a wafer of claim 7, wherein the step of polishing the surface of the ceramic wafer provides a surface root mean square (rms) roughness of less than five nanometers (nm).

9. The method for forming an integrated circuit (IC) coupled to a wafer of claim 7, wherein the ceramic wafer comprises a material selected from the following materials: hot-pressed silicon carbide (SiC), sintered SiC, SiC formed by chemical vapor deposition (CVD SiC), and aluminum nitride (AlN).

10. The method for forming an integrated circuit (IC) coupled to a wafer of claim 7, wherein the step of coupling the active layer comprising the IC to the surface of the ceramic wafer comprises direct bonding the active layer comprising the IC to the surface of the ceramic wafer.

11. The method for forming an integrated circuit (IC) coupled to a wafer of claim 7, further comprising a step of removing the planarization layer and the transfer wafer.

12. A method for forming an integrated circuit (IC) coupled to a wafer, comprising:
a) forming an intermediate layer on a surface of a ceramic wafer;
b) polishing a surface of the intermediate layer;
c) forming an active layer comprising the IC on a silicon substrate;
d) forming a planarization layer on the active layer comprising the IC;
e) coupling a transfer wafer to the planarization layer;
f) removing the silicon substrate from the active layer comprising the IC; and,
g) coupling the active layer comprising the IC to the surface of the intermediate layer.

13. The method for forming an integrated circuit (IC) coupled to a wafer of claim 12, wherein the intermediate layer comprises a material selected from the following materials: silicon carbide, silicon dioxide, silicon nitride and diamond.

14. The method for forming an integrated circuit (IC) coupled to a wafer of claim 12, wherein the ceramic wafer comprises a material selected from the following materials: hot-pressed silicon carbide (SiC), sintered SiC, SiC formed by chemical vapor deposition (CVD SiC), and aluminum nitride (AlN).

15. The method for forming an integrated circuit (IC) coupled to a wafer of claim 12, wherein the step of polishing the surface of the intermediate layer provides a surface root mean square (rms) roughness of less than five nanometers (nm).

16. The method for forming an integrated circuit (IC) coupled to a wafer of claim 12, wherein the step of coupling the active layer comprising the IC to the surface of the ceramic wafer comprises direct bonding the active layer comprising IC components to the surface of the intermediate layer.

17. The method for forming an integrated circuit (IC) coupled to a wafer of claim 12, further comprising a step of removing the planarization layer and the transfer wafer.
